(19) United States
(12) Patent Application Publication
(10) Pub. No.: US 2020/0017965 A1
(43) Pub. Date: Jan. 16, 2020

(54) SUBSTRATE-CARRIER STRUCTURE

(71) Applicant: SGL CARBON SE, Wiesbaden (DE)

(72) Inventors: Shane BRAUN, St. Marys, PA (US); Jonathan KUNTZ, St. Marys, PA (US); Joshua AUMAN, St. Marys, PA (US); Joseph WENDEL, St. Marys, PA (US); Austin MOHNEY, St. Marys, PA (US); Tom GOETZ, St. Marys, PA (US)

(73) Assignee: SGL CARBON SE, Wiesbaden (DE)

(21) Appl. No.: 16/489,123

(22) PCT Filed: Feb. 28, 2018
(86) PCT No.: PCT/EP2018/054988

§ 371 Date: Aug. 27, 2019

Related U.S. Application Data
(60) Provisional application No. 62/464,551, filed on Feb. 28, 2017.

(51) Int. Cl. C23C 16/458; C23C 14/50; C30B 25/12; H01L 21/687

(52) U.S. Cl. CPC C23C 16/4583; C23C 14/50; H01L 21/68785; C23C 16/4581; C30B 25/12

(57) ABSTRACT

A substrate carrier structure wherein the substrate may be a wafer and its use in nanoscale processes, such as deposition and/or growth processes. The carrier structure comprises grooves on its frontside and or backside.

This invention relates to a novel substrate carrier structure wherein the substrate may be a wafer and its use in nanoscale processes, such as deposition and/or growth processes.

With the industry's trend towards device miniaturization, process consistency becomes a critical factor affecting final yields. These trends are observed in industries such as semiconductor, solar, epitaxial growth, and LED production. In order to produce the aforementioned nanoscale structures these industries use several deposition and growth techniques including CVD (Chemical Vapor Deposition), VPE (Vapor Phase Epitaxy) and PVD (Physical Vapor Deposition). Specifically, thin films produced by these techniques can have structures including monocrystalline, polycrystalline, and/or amorphous phases. In each process technique a substrate-carrier structure, is required.

Many of these substrate-carrier structures comprise a carrier structure containing at least one pocket which physically supports the wafer substrate to provide heat dissipation and transfer during the growth/deposition processes (W. S. Rees, CVD of nonmetals, Wiley-VCH, Weinheim, 1996; A. C. Jones, P. O'Brien, CVD of Compound Semiconductors, VCH, Weinheim, 1997). The profile of the pocket floor can contribute to a consistent heat transfer across the surface of the wafer substrate. This temperature of the wafer is one of the main factors influencing film properties in the above mentioned deposition and growth processes. US 2013/0319319 describe a substrate-carrier structure wherein the carrier structure comprises a pocket which is placed on the backside of the carrier structure and wherein this pocket has a two-stage structure, i.e. an upper-stage portion and a lower-stage portion. By using such a two-stage structure of the pocket the thermal transfer at the edge of the wafer substrate is improved, however, the heat transfer across the surface of the wafer substrate is not uniform.

The uniformity of the heat transfer influences the film properties in the deposition and growth processes mentioned above. By having a non-uniform heat transfer across the surface of the wafer substrate the thickness of the deposited film can be unequal resulting in an insufficient yield of the deposited layers.

The object of the present invention is therefore to provide an improved substrate-carrier structure increasing the uniformity and yield of the layers deposited during the growth/deposition process on the substrate which may be a wafer.

This object is solved by a substrate-carrier structure wherein the backside and/or frontside of the carrier structure, preferably the backside, comprises at least one groove.

One factor which influences the uniformity of the heat transfer across the surface of the substrate is the mechanical support/stability to the overall carrier structure. By having at least one groove in the carrier structure mechanical support to the surface of the carrier structure is given; in particular the mechanical deformation of the carrier substrate perpendicular to said surface is prevented. Such a carrier structure has a decreased shape compared to prior art substrates carriers having no grooves. This groove/these grooves reduce variability in flatness of the carrier structure wherein the design of the carrier structure can preferably be adapted to gas delivery systems and heating elements being used in the corresponding growth/deposition process. The arrangement of the at least one groove on the carrier can be radial or concentric or it can be combination of a radial and concentric arrangement. In the context of the present invention a radial groove is defined as a groove extending from the edge to the center of the substrate-carrier structure and a concentric groove shows no interruption around the perimeter. The concentric grooves prevent a height runout around the perimeter of the substrate-carrier structure. This means that the circular grooves ensure that the carrier shape is more uniform and not saddle-shaped, which would be higher in one axis than the other. This has the further advantage that during the use of the substrate carrier-structure in a growth process, the coated substrates are heated and coated equally, which results in a higher quality of the coated products. The number of grooves is not limited, however, it is preferred that in case of radial grooves the number thereof is in the range of 1 to 18, preferably of 2 to 16, more preferably in the range of 2 to 14 and in case of concentric grooves the number thereof is preferably in the range of 1 to 6, more preferably of 2 to. If a combination of radial and concentrical grooves is used the numbers of grooves mentioned before are valid.

The cross-sectional design of a groove/the grooves can be angular (V-shape), rectangular, or circular. If more than one groove is present the cross-sectional design of each groove can be the same or it can be any combination of the mentioned cross-sectional designs.

The depth of the grooves is no larger than 90% of the total substrate carrier thickness, i.e. these grooves do not represent through holes. Above a depth of 90% of the total substrate-carrier structure thickness the substrate-carrier structure becomes brittle and below a depth of 1% of the total substrate-carrier structure thickness no effect of the grooves can be seen. The width to depth ratio of the groove is less than 10. If a radial design of the grooves is chosen the length of each groove is preferably smaller than the radius of the carrier structure, typically by less than 95% of the carrier radius. However, it is also possible that the length extends through the carrier center or to the carrier edge.

It is to be understood that the cross-sectional design, the depth and the aspect ratio of the groove(s) depend on conditions of the deposition and/or growth process used, i.e. on the desired properties of the product resulting from such a process.

The inventive carrier structure further comprises at least one pocket being part of the frontside of the carrier structure.

The uniformity of the heat transfer across the surface of the substrate is also influenced by the contact surfaces of the substrate and of the carrier and by the spacing between the substrate and the pocket surface(s).

The pocket floor profile should be engineered in such a way to provide a consistent heat transfer across the surface of the wafer substrate. For substrate-carrier structures containing multiple pockets this uniformity must translate to all pockets. Independent of the number of pockets on a given substrate-carrier structure, each pocket's dimensions are influenced by the overall carrier shape which is influenced by the grooves. This shape is defined as the physical deflection both circumferentially and across the diameter of the substrate carrier. Failure to provide consistent substrate-carrier structure shape/flatness will ultimately lead to pocket structure variability and therefore poor process uniformity and yield of the layers deposited during the growth/deposition process on the substrate.

The profile of the pocket(s) can be flat, concave or convex or any combination thereof. The more uniform shape of the carrier results in lower scrap rates due to the higher uniformity of the deposited layers on the substrate-wafer during the growth process increases, because the flattness and shape of the pockets support a uniform temperature distribution.

The number of pockets depends on the dimensions of the carrier structure and on the desired properties of the final product. Advantageously the pockets have a diameter of 25-500 mm, preferably 45-455 mm, more preferably 45-305 mm.

The carrier is made of a material selected from the group consisting of graphite, silicon carbide, graphite or coated with silicon carbide or carbonfiber reinforced carbon (CFRC) coated with silicon carbide or any arbitrary mixture thereof.

The inventive substrate-carrier structure can be used in epitaxial, polycrystalline, or amorphous growth production processes, like CVD (Chemical Vapor Deposition), VPE (Vapor Phase Epitaxy), and PVD (Physical Vapor Deposition).

In the following, the present invention is described purely by way of example with reference to advantageous embodiments and with reference to the accompanying drawings.

### EXAMPLES

### Example 1

According to this example a graphite carrier contains at least 3 radial grooves extending from the near center of the carrier to the near edge. These radial grooves, preferably symmetrically arranged, provide rigidity along the carrier radius to mitigate deflection that would otherwise cause the carrier to move convex or concave. This reduction in carrier deflection variability leads to a more consistent pocket floor profile, providing the targeted wafer-to-carrier spacing to enhance within-wafer uniformity and subsequently yield.

If for example 150 mm susceptors having for example 12 radial grooves are used it is possible to get a pocket profile having around 0.002 inches, whereas if no grooves are used it is only possible to get a pocket profile of around 0.004 inches.

| | Wafer susceptor without | Wafer susceptor with |
|---|---|---|
| Statistics | grooves | grooves |
| N | 320 | 190 |
| Mean | 0.0041513 (inches) | 0.0023538 (inches) |
| Standard Deviation | 0.0010562 (inches) | 0.0010108 (inches) |
| Minimum | 0.0013296 (inches) | 0.000312 (inches) |
| Maximum | 0.0062436 (inches) | 0.0045615 (inches) |

N = number of wafer susceptor

### Example 2

According to this example a graphite carrier contains at least one circular groove, preferably three circular grooves being concentric with the carrier. This circular feature acts to increase the rigidity of the carrier around the circumference to mitigate deflection that would otherwise cause the carrier to bend or warp. This provides a uniformly flat carrier edge, serving two main purposes; Pocket floor profiles would be more consistent due to the lack in carrier shape variability. Also, the spacing between the carrier and reactor components would be more consistent. These components could include heat sources, gas delivery systems, or metrology equipment in which spacing is critical to the operation. Consistency in the space between the carrier and the components will provide more uniform deposition or growth parameters (temperature, concentration, pressure, flow rate, etc.) Furthermore, the concentric grooves ensure that the pockets of the carrier are flat and not convex resulting in substrates being equally heated and coated.

### Example 3

According to this example a graphite carrier contains at least 1 circular groove and at least 3 radial grooves. The radial grooves provide rigidity along the substrate-carrier structure radius to mitigate deflection that otherwise cause the substrate-carrier structure to move convex or concave. In parallel the circular groove acts to increase the rigidity of the carrier around the circumference to mitigate deflection that otherwise cause the carrier to bend or warp. As result, pocket floor profiles would be more consistent due to the lack in the substrate-carrier structure shape variability. This reduction in substrate-carrier structure deflection variability leads to a more consistent pocket floor profile. This further results in a more unformily deposited/grown layer on the wafer-substrate, because the spacing between the substrate-carrier structure and the substrate-wafer is optimized and the temperature distribution is improved. This has the further advantage that during the use of the substrate carrier-structure in a growth process, the coated substrates are heated and coated equally, which results in a higher quality of the coated products. In addition, the spacing between the carrier and reactor components is more consistent. These components could include heat sources, gas delivery systems, or metrology equipment in which spacing is critical to the operation. Consistency in the space between the carrier and the components provide a more uniform deposition or growth parameters (i.e. temperature, concentration, pressure, flow rate).

### FIGURES

FIG. 1 shows a carrier in a top view only having circular grooves

FIG. 2 shows a carrier in a top view only having radial grooves

FIG. 3 shows a carrier in a top view having radial and circular grooves

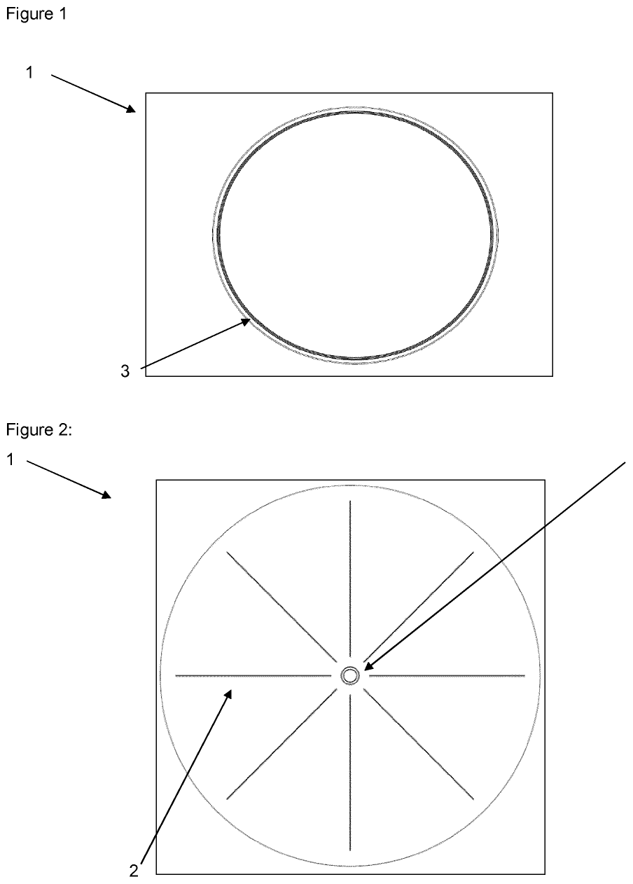

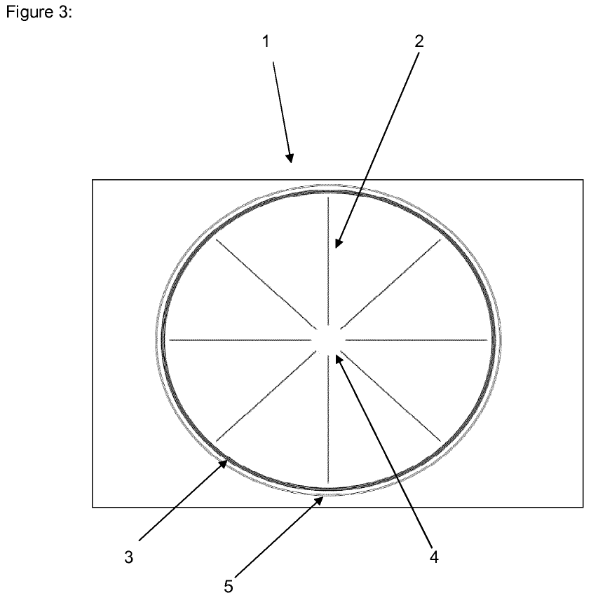

### REFERENCE LIST

1 substrate-carrier structure
2 radial groove
3 circular groove
4 center of the substrate-carrier structure
5 edge of the substrate-carrier structure

1-10. (canceled)

11. A substrate-carrier structure, wherein the backside and/or frontside of the carrier structure comprises at least one groove.

12. The substrate-carrier structure according to claim 11, wherein the at least one groove is arranged radial and/or concentric.

13. The substrate-carrier structure according to claim 11, wherein the at least one groove has a design, when viewed in cross-section, which is angular, rectangular or circular.

14. The substrate-carrier structure according to claim 11, wherein the at least one groove has a depth in the range of 1% to 90% of the total substrate carrier structure thickness.

15. The substrate-carrier structure according to claim 11, wherein the width to depth ratio of the at least one groove is less than 10.

16. The substrate-carrier structure according to claim 11, wherein the frontside of the carrier structure further comprises at least one pocket.

17. The substrate-carrier structure according to claim 16, wherein the at least one pocket has a flat, concave or convex profile.

18. The substrate-carrier structure according to claim 16, wherein the at least one pocket has a diameter of 25 to 500 mm.

19. The substrate-carrier structure according to claim 11, wherein the carrier is made of a material selected from the group consisting of graphite, silicon carbide, graphite or coated with silicon carbide or carbonfiber reinforced carbon (CFRC) coated with silicon carbide or any arbitrary mixture thereof.

20. A use of the substrate carrier-structure according to claim 11 for epitaxial, polycrystalline, or amorphous growth production processes.

21. A use of the substrate carrier-structure according to claim 12 for epitaxial, polycrystalline, or amorphous growth production processes.

22. The substrate-carrier structure according to claim 12, wherein the at least one groove has a design, when viewed in cross-section, which is angular, rectangular or circular.
